(19) United States
(12) Patent Application Publication
(10) Pub. No.: US 2024/0276720 A1
(43) Pub. Date: Aug. 15, 2024

(54) SEMICONDUCTOR MEMORY DEVICE

(71) Applicant: SAMSUNG ELECTRONICS CO., LTD., Suwon-si (KR)

(72) Inventors: Kohji KANAMORI, Suwon-si (KR); Jeehoon HAN, Suwon-si (KR)

(21) Appl. No.: 18/404,079

(22) Filed: Jan. 4, 2024

(30) Foreign Application Priority Data
Feb. 10, 2023 (KR) 10-2023-0017877

(51) Int. Cl. H10B 43/27; H01L 29/423; H10B 41/10; H10B 41/27; H10B 43/10

(52) U.S. Cl. CPC H10B 43/27; H01L 29/4236; H10B 41/10; H10B 41/27; H10B 43/10

(57) ABSTRACT

A semiconductor memory device includes structures including insulation layers and semiconductor layers alternately stacked in a vertical direction, the structures being spaced apart from one another in a horizontal direction; an interlayer insulation layer between the structures; gate electrodes respectively in gate trenches passing through the interlayer insulation layer in the vertical direction, between the structures, the gate electrodes connected to the semiconductor layers; and vertical insulation layers respectively on sidewalls of the gate trenches, wherein each gate electrode includes first portions overlapping the insulation layers in the horizontal direction and second portions overlapping the semiconductor layers in the horizontal direction, and a first width of each first portion in the horizontal direction is greater than a second width of each second portion in the horizontal direction.

### CROSS-REFERENCE TO RELATED APPLICATION

This application is based on and claims priority under 35 U.S.C. § 119 to Korean Patent Application No. 10-2023-0017877, filed on Feb. 10, 2023, in the Korean Intellectual Property Office, the disclosure of which is incorporated by reference herein in its entirety.

### BACKGROUND

### 1 Field

Embodiments relate to a semiconductor memory device.

### 2. DESCRIPTION OF THE RELATED ART

As the electronic industry advances rapidly and the demands of users increase, electronic devices are being more and more miniaturized and light. Therefore, semiconductor devices which are high in degree of integration and are used in electronic devices are needed, and thus, a design rule for elements of semiconductor devices may be reduced.

### SUMMARY

The embodiments may be realized by providing a semiconductor memory device including a plurality of structures including a plurality of insulation layers and a plurality of semiconductor layers alternately stacked in a vertical direction, the plurality of structures being spaced apart from one another in a horizontal direction; an interlayer insulation layer between the plurality of structures; a plurality of gate electrodes respectively in a plurality of gate trenches passing through the interlayer insulation layer in the vertical direction, between the plurality of structures, the plurality of gate electrodes connected to the plurality of semiconductor layers; and a plurality of vertical insulation layers respectively on sidewalls of the plurality of gate trenches, wherein each gate electrode of the plurality of gate electrodes includes a plurality of first portions overlapping the plurality of insulation layers in the horizontal direction and a plurality of second portions overlapping the plurality of semiconductor layers in the horizontal direction, and a first width of each first portion of the plurality of first portions in the horizontal direction is greater than a second width of each second portion of the plurality of second portions in the horizontal direction.

The embodiments may be realized by providing a semiconductor memory device including a first structure including a plurality of first insulation layers and a plurality of first semiconductor layers, which are alternately stacked in a vertical direction; a second structure including a plurality of second insulation layers and a plurality of second semiconductor layers, which are alternately stacked in the vertical direction, the second structure being spaced apart from the first structure in a first horizontal direction; a third structure including a plurality of third insulation layers and a plurality of third semiconductor layers, which are alternately stacked in the vertical direction, the third structure being spaced apart from the second structure in the first horizontal direction; a first interlayer insulation layer between the first structure and the second structure; a second interlayer insulation layer between the second structure and the third structure; a plurality of first gate electrodes respectively in a plurality of first gate trenches aligned in a second horizontal direction intersecting with the first horizontal direction, passing through the first interlayer insulation layer in the vertical direction, and connected to the plurality of first semiconductor layers and the plurality of second semiconductor layers; and a plurality of second gate electrodes respectively in a plurality of second gate trenches aligned in the second horizontal direction, passing through the second interlayer insulation layer in the vertical direction, and connected to the plurality of second semiconductor layers and the plurality of third semiconductor layers, wherein a center of each first gate electrode of the plurality of first gate electrodes and a center of each second gate electrode of the plurality of second gate electrodes are offset in the first horizontal direction, and a width of each first semiconductor layer of the plurality of first semiconductor layers in the first horizontal direction is greater than a width of each first insulation layer of the plurality of first insulation layers in the first horizontal direction.

The embodiments may be realized by providing a semiconductor memory device including a plurality of structures including a plurality of insulation layers and a plurality of semiconductor layers alternately stacked in a vertical direction, the plurality of structures being spaced apart from one another in a first horizontal direction; an interlayer insulation layer between the plurality of structures; a plurality of gate electrodes respectively in a plurality of gate trenches passing through the interlayer insulation layer in the vertical direction, between the plurality of structures, the plurality of gate electrodes being connected to the plurality of semiconductor layers; and a plurality of vertical insulation layers respectively on inner sidewalls of the plurality of gate trenches, wherein each gate electrode of the plurality of gate electrodes includes a plurality of first portions overlapping the plurality of insulation layers in the first horizontal direction and a plurality of second portions overlapping the plurality of semiconductor layers in the first horizontal direction, a first width of each first portion of the plurality of first portions in the first horizontal direction is greater than a second width of each second portion of the plurality of second portions in the first horizontal direction, a width of each first portion of the plurality of first portions in a second horizontal direction is equal to a width of each second portion of the plurality of second portions in the second horizontal direction, the plurality of gate trenches are arranged in zigzags in a plan view, and each semiconductor layer of the plurality of semiconductor layers has a shape that is rounded at a contact surface with the plurality of gate trenches.

### BRIEF DESCRIPTION OF THE DRAWINGS

Features will be apparent to those of skill in the art by describing in detail exemplary embodiments with reference to the attached drawings in which:

FIG. 1 is a block diagram of a semiconductor memory device according to embodiments;

FIG. 2 is a perspective view of a memory cell array of a semiconductor memory device according to embodiments;

FIG. 3 is a plan view illustrating a top view of a semiconductor layer of a memory cell array of a semiconductor memory device according to embodiments;

FIG. 4 is a plan view illustrating a top view of a word line of a memory cell array of a semiconductor memory device according to embodiments;

FIG. 5 is a plan view illustrating a top view of a bit line of a memory cell array of a semiconductor memory device according to embodiments;

FIGS. 6A to 6C are diagrams for describing some elements of a semiconductor memory device according to embodiments;

FIGS. 7A and 7B are diagrams for describing some elements of a semiconductor memory device according to other embodiments; and

FIGS. 8A to 13B are diagrams of stages in a method of manufacturing some elements of a semiconductor memory device, according to an embodiment.

### DETAILED DESCRIPTION

Hereinafter, embodiments will be described in detail with reference to the accompanying drawings.

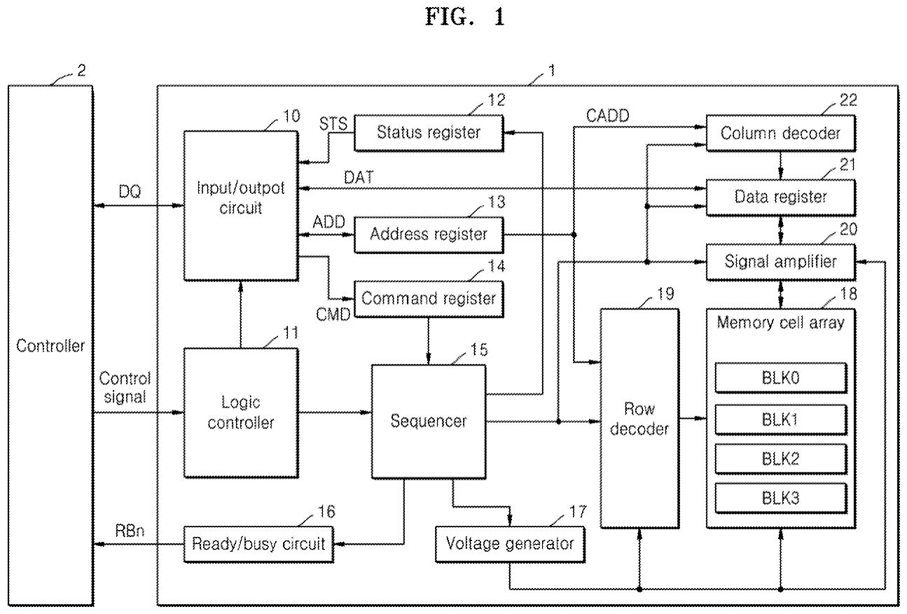

FIG. 1 is a block diagram of a semiconductor memory device 1 according to embodiments. A total configuration of the semiconductor memory device 1 will be described with reference to FIG. 1. In an implementation, as illustrated in FIG. 1, some couplings between blocks may be illustrated by arrows.

As illustrated in FIG. 1, the semiconductor memory device 1 may include an input/output circuit 10, a logic controller 11, a status register 12, an address register 13, a command register 14, a sequencer 15, a ready/busy circuit 16, a voltage generator 17, a memory cell array 18, a row decoder 19, a signal amplifier 20, a data register 21, and a column decoder 22.

The input/output circuit 10 may control an input and an output of a signal DQ from or to an external controller 2. The signal DQ may include, e.g., data DAT, an address ADD, and a command CMD. In an implementation, the input/output circuit 10 may transfer the data DAT, received from the external controller 2, to the data register 21, transfer the address ADD to the address register 13, and transfer the command CMD to the command register 14. The input/output circuit 10 may also transfer, to the external controller 2, status information STS received from the status register 12, the data DAT received from the data register 21, and the address ADD received from the address register 13.

The logic controller 11 may receive various kinds of control signals from the external controller 2. The logic controller 11 may control the input/output circuit 10 and the sequencer 15, based on the received control signal.

The status register 12 may temporarily store, e.g., the status information STS in performing a write operation, a read operation, or an erase operation and may notify the external controller 2 whether an operation is normally completed.

The address register 13 may temporarily store the received address ADD. The address register 13 may transfer a row address RADD to the row decoder 19 and may transfer a column address CAD to the column decoder 22.

The command register 14 may temporarily store the received command CMD and may transfer the command CMD to the sequencer 15.

The sequencer 15 may control the overall operation of the semiconductor memory device 1. In detail, based on the received command CMD, the sequencer 15 may control the status register 12, the ready/busy circuit 16, the voltage generator 17, the row decoder 19, the signal amplifier 20, the data register 21, and the column decoder 22 and may perform a write operation, a read operation, and an erase operation.

The ready/busy circuit 16 may transfer a ready/busy signal RBn to the external controller 2 based on an operation status of the sequencer 15.

Based on control by the sequencer 15, the voltage generator 17 may generate voltages for a write operation, a read operation, and an erase operation and may supply the generated voltages to, e.g., the memory cell array 18, the row decoder 19, and the signal amplifier 20. The row decoder 19 and the signal amplifier 20 may apply the voltages, supplied from the voltage generator 17, to memory cell transistors of the memory cell array 18.

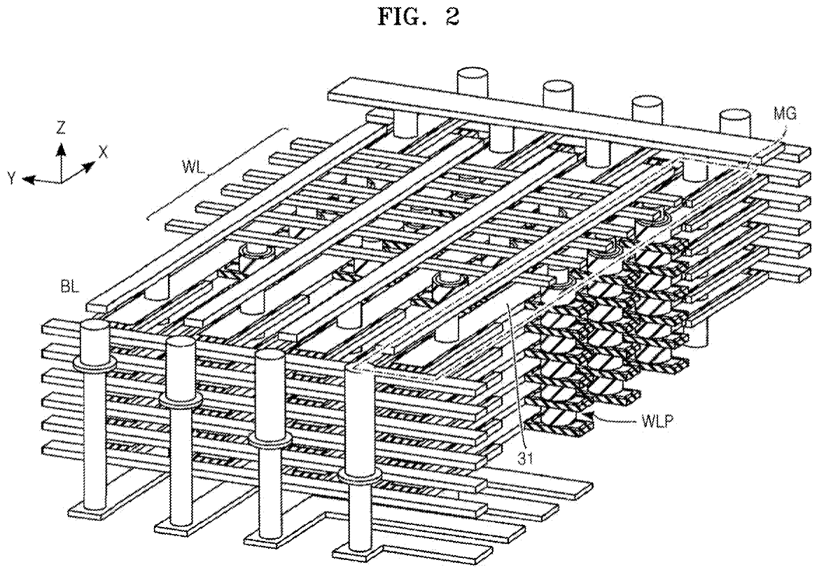

The memory cell array 18 may include a plurality of blocks BLK (e.g., BLK0 to BLK3) including a plurality of non-volatile memory cell transistors (hereinafter referred to as a memory cell) associated with the row and the column. Each of the blocks BLK may include a plurality of memory units. Each of the memory units may include a plurality of memory groups MG (see FIG. 2). The memory cell array 18 will be described below.

The row decoder 19 may decode the row address RADD. Based on a decoding result, the row decoder 19 may apply a desired voltage to the memory cell array 18.

In a read operation, the signal amplifier 20 may sense read data from the memory cell array 18. The signal amplifier 20 may transfer the read data to the data register 21. In a write operation, the signal amplifier 20 may transfer write data to the memory cell array 18.

The data register 21 may include a plurality of latch circuits. Each of the plurality of latch circuits may temporarily retain write data or read data.

In performing a write operation, a read operation, or an erase operation, the column decoder 22 may decode the column address CADD and may select a latch circuit in the data register 21 based on a decoding result.

FIG. 2 is a perspective view of a memory cell array of a semiconductor memory device according to embodiments. In FIG. 2, an insulation layer may be partially omitted.

Referring to FIG. 2, the memory cell array may include a plurality of semiconductor layers 31, a plurality of word line pillars WLP, a plurality of word lines WL, and a plurality of bit lines BL.

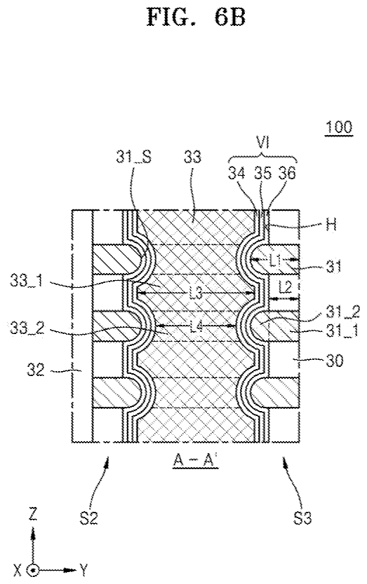

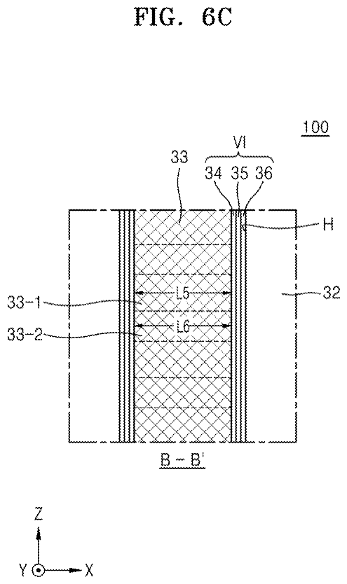

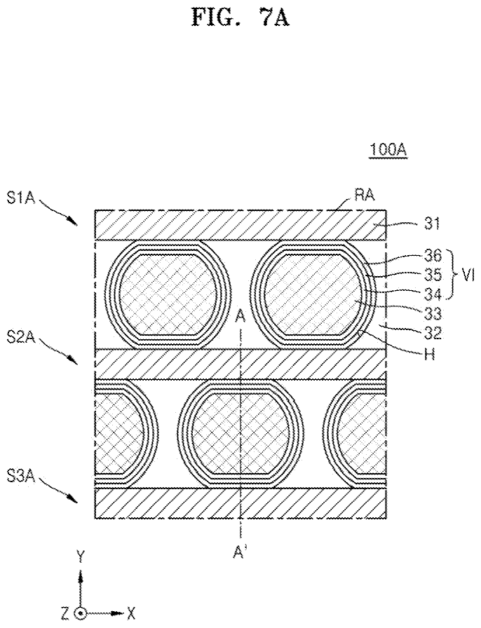

In an implementation, each of the plurality of semiconductor layers 31 may correspond to one memory group MG. Each of the plurality of semiconductor layers 31 may function as an active region where channel layers of a plurality of memory cell transistors MC (see FIG. 6) and selection transistors are provided. The plurality of semiconductor layers 31 may extend in a first horizontal direction (the X direction) and may be stacked in the vertical direction (the Z direction). In an implementation, the plurality of semiconductor layers 31 may be spaced apart from each other with an insulation layer therebetween. The plurality of semiconductor layers 31 may be arranged apart from one another in a second horizontal direction (the Y direction) intersecting with the first horizontal direction (the X direction).

In an implementation, the plurality of word line pillars WLP may be arranged in the first horizontal direction (the X direction) and may extend in the vertical direction (the Z direction) between the plurality of semiconductor layers 31 in the second horizontal direction (the Y direction). In an implementation, groups of the plurality of semiconductor layers 31 stacked in the vertical direction (the Z direction) and the plurality of word line pillars WLP arranged in the first horizontal direction (the X direction) may be alternately arranged in the second horizontal direction (the Y direction). The word line WL may extend in the second horizontal direction (the Y direction), on the word line pillar WLP. A tunneling dielectric layer, a charge storage layer, and a blocking dielectric layer, as described below, may be between the plurality of semiconductor layers 31 and the word line pillar WLP.

In an implementation, one memory cell transistor MC may be at an intersection point between each word line pillar WLP and a semiconductor layer 31 corresponding thereto. In an implementation, the plurality of memory cell transistors MC may be connected with one another in the first horizontal direction (the X direction) through the semiconductor layer 31 thereof. In an implementation, channels of the memory cell transistors MC may be coupled to each other in the first horizontal direction (the X direction).

In an implementation, a plurality of memory groups MG (i.e., the plurality of semiconductor layers 31) arranged in the second horizontal direction (the Y direction) may be included in one memory unit.

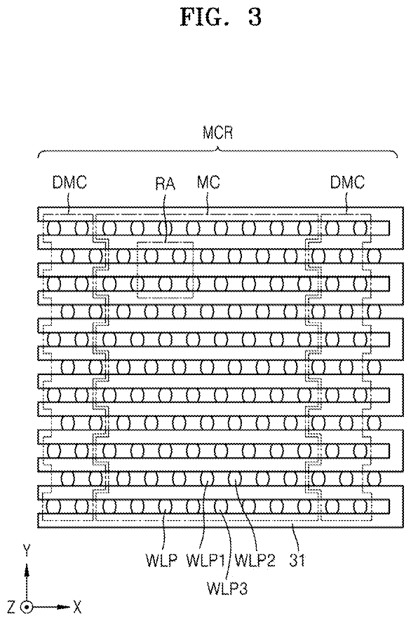

FIG. 3 is a plan view illustrating a top view of a semiconductor layer 31 of a memory cell array 18 (see FIG. 1) of a semiconductor memory device according to embodiments. In detail, FIG. 3 is a plan view illustrating a semiconductor layer 31 of an uppermost layer of a memory cell region MCR of the memory cell array 18 of the semiconductor memory device according to embodiments.

Referring to FIG. 3, a memory cell transistor MC (i.e., a word line pillar WLP) may be in the memory cell region MCR.

In an implementation, a plurality of semiconductor layers 31 may extend (e.g., lengthwise) in a first horizontal direction (the X direction) and may be arranged in a second horizontal direction (the Y direction), in the memory cell region MCR. A plurality of word line pillars WLP may be arranged in the first horizontal direction (the X direction) between two semiconductor layers 31. In an implementation, the plurality of word line pillars WLP may be arranged to be staggered in the second horizontal direction (the Y direction). In an implementation, a first word line pillar WLP1 and a second word line pillar WLP2 may be adjacent to each other in the first horizontal direction (the X direction), and when seen in the second horizontal direction (the Y direction), a third word line pillar WLP3 may be between the first word line pillar WLP1 and the second word line pillar WLP2 and may be apart from the first word line pillar WLP1 and the second word line pillar WLP2 in the second horizontal direction (the Y direction).

In an implementation, as illustrated in FIG. 3, four word line pillars WLP disposed two by two at each of both ends among twelve word line pillars WLP arranged in the first horizontal direction (the X direction) between two semiconductor layers 31 may correspond to a dummy memory cell transistor DMC (hereinafter referred to as a dummy cell). In an implementation, two dummy memory cell transistors DMC, eight memory cell transistors MC, and two dummy memory cell transistors DMC may be sequentially arranged in the first horizontal direction (the X direction). In an implementation, the dummy memory cell transistor DMC may be used to electrically couple a selection transistor to a channel region of a memory cell transistor MC in the semiconductor layer 31 of the memory cell region MCR. In an implementation, the number of dummy memory cell transistors DMC may be 0.

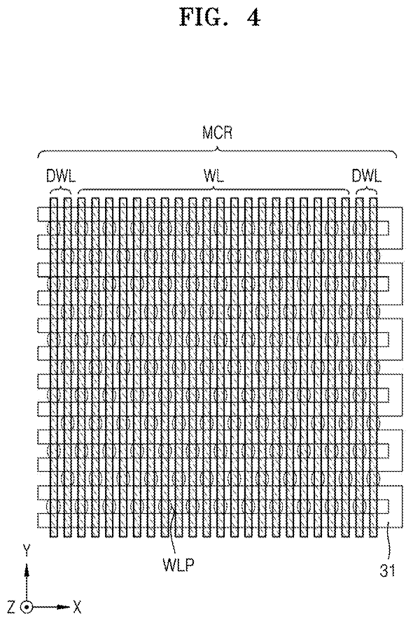

FIG. 4 is a plan view illustrating a top view of a word line WL of a memory cell array 18 of a semiconductor memory device according to embodiments. In detail, FIG. 4 is a plan view illustrating the word line WL of a memory cell region MCR of the memory cell array 18 of the semiconductor memory device according to embodiments.

Referring to FIG. 4, a plurality of word lines WL may extend in a second horizontal direction (the Y direction) and may be apart from one another in a first horizontal direction (the X direction), in the memory cell region MCR. The plurality of word lines WL may be on a plurality of word line pillars WLP and may be electrically coupled to a plurality of word line pillars WLP. A pitch between the plurality of word lines WL in the first horizontal direction (the X direction) may be, e.g., ½ of a pitch between the plurality of word line pillars WLP in the first horizontal direction (the X direction). In an implementation, the pitch between the plurality of word lines WL in the first horizontal direction (the X direction) may be, e.g., ¼ of the pitch between the plurality of word line pillars WLP in the first horizontal direction (the X direction).

FIG. 4 illustrates a case where 24 word lines WL are arranged in the first horizontal direction (the X direction) and total four word lines WL disposed two by two at each of both ends correspond to a dummy word line DWL. In an implementation, the number and arrangement of dummy word lines DWL may be 0.

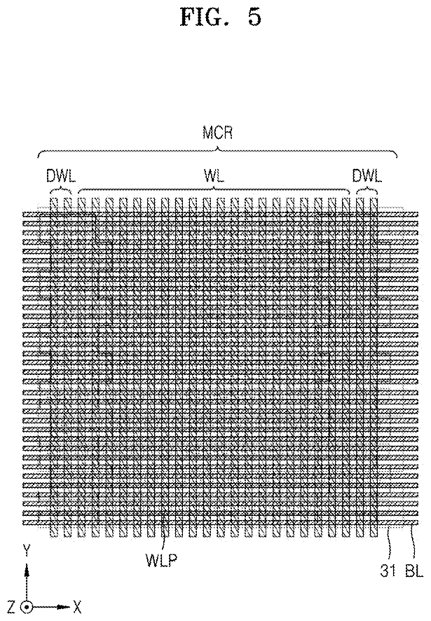

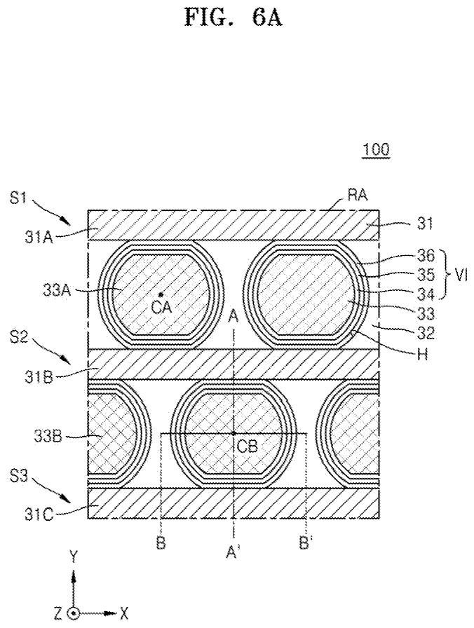

FIG. 5 is a plan view illustrating a top view of a bit line BL of a memory cell array 18 of a semiconductor memory device according to embodiments. In detail, FIG. 5 is a plan view illustrating the bit line BL of a memory cell region MCR of the memory cell array 18 of the semiconductor memory device according to embodiments. FIG. 5 illustrates, e.g., a case where the bit line BL is on a word line WL.

Referring to FIG. 5, a plurality of bit lines BL may extend in a first horizontal direction (the X direction) and may be arranged in a second horizontal direction (the Y direction), on the word line WL.

FIGS. 6A to 6C are diagrams for describing some elements of a semiconductor memory device 100 according to embodiments. In detail, FIG. 6A is an enlarged plan view of a region RA of FIG. 3, FIG. 6B is a cross-sectional view taken along line A-A′ of FIG. 6A, and FIG. 6C is a cross-sectional view taken along line B-B′ of FIG. 6A.

A plurality of semiconductor layers 31 and gate electrodes 33 in a memory cell region MCR (see FIG. 3) of a memory cell array 18 (see FIG. 1) of the semiconductor memory device 100 will be described with reference to FIGS. 6A to 6C. Each of the gate electrodes 33 of FIGS. 6A to 6C may include the word line pillar WLP described above with reference to FIGS. 2 and 3 to 5.

In an implementation, the semiconductor memory device 100 may include a plurality of structures S1 to S3 which are apart from one another in a second horizontal direction (the Y direction). Each of the plurality of structures S1 to S3 may include a plurality of semiconductor layers 31 and a plurality of insulation layers 30, which are stacked in the vertical direction (the Z direction).

In an implementation, an interlayer insulation layer 32 may be between the plurality of structures (e.g., first to third structures) S1 to S3. In an implementation, the interlayer insulation layer 32 may be between the first structure S1 and the second structure S2 and between the second structure S2 and the third structure S3. The interlayer insulation layer 32 may extend in the vertical direction (the Z direction).

In an implementation, a plurality of gate trenches H may pass through the interlayer insulation layer 32, between the plurality of structures S1 to S3, in the vertical direction (the Z direction). In an implementation, the plurality of gate trenches H may be between two adjacent structures of the plurality of structures S1 to S3. In an implementation, the plurality of gate trenches H may be between the first structure S1 and the second structure S2 and between the second structure S2 and the third structure S3.

In an implementation, a plurality of gate electrodes 33 extending in the vertical direction (the Z direction) may be in each of the plurality of gate trenches H. A plurality of vertical insulation layers VI extending in the vertical direction (the Z direction) may be between the plurality of gate electrodes 33 and a sidewall of each of the plurality of gate trenches H. Each of the plurality of vertical insulation layers VI may include a blocking dielectric layer 34, a charge storage layer 35, and a tunneling dielectric layer 36, which are sequentially arranged on an outer sidewall of each of the plurality of gate electrodes 33.

In an implementation, the blocking dielectric layer 34 may include silicon oxide, hafnium oxide, aluminum oxide, zirconium oxide, or tantalum oxide. The charge storage layer 35 may be a region which may store electrons passing through the blocking dielectric layers 34 from the gate electrode 33 and may include silicon nitride, boron nitride, silicon boron nitride, or polysilicon doped with impurities. The tunneling dielectric layer 36 may include silicon oxide, silicon nitride, or a metal oxide that is greater in permittivity than silicon oxide. The metal oxide may include hafnium oxide, aluminum oxide, zirconium oxide, tantalum oxide, or a combination thereof. As used herein, the term “or” is not necessarily an exclusive term, e.g., “A or B” would include A, B, or A and B.

In an implementation, as illustrated in FIG. 6B, a boundary between the semiconductor layer 31 and the interlayer insulation layer 32 may be aligned with a boundary between the insulation layer 30 and the interlayer insulation layer 32 in the vertical direction (the Z direction). In an implementation, a boundary between the semiconductor layer 31 and the gate trench H may not be aligned with a boundary between the insulation layer 30 and the gate trench H in the vertical direction (the Z direction).

In an implementation, the semiconductor layer 31 may be recessed toward the gate electrode 33 compared to the plurality of insulation layers 30. In detail, the semiconductor layer 31 may be recessed toward the gate electrode 33 in the second horizontal direction (the Y direction).

In an implementation, the semiconductor layer 31 may include a first portion 31_1 overlapping the insulation layer 30 in the vertical direction (the Z direction) and a second portion 31_2 that does not overlap the insulation layer 30 in the vertical direction (the Z direction). In an implementation, the second portion 31_2 may be between the first portion 31_1 and the gate electrode 33 in the second horizontal direction (the Y direction). In an implementation, the plurality of insulation layers 30 may not include a portion that does not overlap the semiconductor layer 31 in the vertical direction (the Z direction). In an implementation, the second portion 31_2 may be a portion where the semiconductor layer 31 is recessed toward the gate electrode 33.

In an implementation, a contact surface between the semiconductor layer 31 and a sidewall of the gate trench H may be a curved surface. In an implementation, the second portion 31_2 that does not overlap the insulation layer 30 in the vertical direction (the Z direction) may have a shape that is rounded at a boundary with the gate trench H. In an implementation, the second portion 31_2 may have a shape that differs at a boundary with the first portion 31_1 and a boundary with the gate trench H. In an implementation, a portion, recessed toward the gate electrode 33, of the semiconductor layer 31 may have a rounded shape.

In an implementation, a width L1 of the semiconductor layer 31 in the second horizontal direction (the Y direction) may be greater than a width L2 of the insulation layer 30 in the second horizontal direction (the Y direction). In an implementation, the width L1 of the semiconductor layer 31 in the second horizontal direction (the Y direction) may be changed in the vertical direction (the Z direction), and the width L2 of the insulation layer 30 in the second horizontal direction (the Y direction) may be substantially constant in the vertical direction (the Z direction). In an implementation, the maximum width of the semiconductor layer 31 in the second horizontal direction (the Y direction) may be greater than the width L2 of the insulation layer 30 in the second horizontal direction (the Y direction). In an implementation, an average width of the semiconductor layer 31 in the second horizontal direction (the Y direction) may be greater than an average width of the insulation layer 30 in the second horizontal direction (the Y direction). In an implementation, a width of the semiconductor layer 31 at a middle vertical level in the second horizontal direction (the Y direction) may be greater than a width of the insulation layer 30 at a middle vertical level in the second horizontal direction (the Y direction).

In an implementation, the width L1 of the semiconductor layer 31 in the second horizontal direction (the Y direction) may increase in or along the vertical direction (the Z direction) (e.g., to a maximum width), and then may decrease. An increased width or a decreased width of the width L1 of the semiconductor layer 31 in the second horizontal direction (the Y direction) may not be constant in the vertical direction (the Z direction).

In an implementation, the gate electrode 33 may include a plurality of first portions 33_1 overlapping the insulation layer 30 in the second horizontal direction (the Y direction) and a plurality of second portions 33_2 overlapping the semiconductor layer 31 in the second horizontal direction (the Y direction). In an implementation, the first portion 33_1 and the second portion 33_2 may be alternately arranged in the vertical direction (the Z direction).

In an implementation, a width L3 of the first portion 33_1, overlapping the insulation layer 30 in the second horizontal direction (the Y direction), in the second horizontal direction (the Y direction) may be greater than a width L4 of the second portion 33_2, overlapping the semiconductor layer 31 in the second horizontal direction (the Y direction), in the second horizontal direction (the Y direction). In an implementation, the width L3 of the first portion 33_1 in the second horizontal direction (the Y direction) and the width L4 of the second portion 33_2 in the second horizontal direction (the Y direction) may not be constant in the vertical direction (the Z direction). Also, as the first portion 33_1 contacts the second portion 33_2, the first portion 33_1 and the second portion 33_2 may have the same width in the second horizontal direction (the Y direction) at a boundary between the first portion 33_1 and the second portion 33_2. In an implementation, the maximum width of the first portion 33_1 in the second horizontal direction (the Y direction) may be greater than the maximum width of the second portion 33_2 in the second horizontal direction (the Y direction). In an implementation, the minimum width of the first portion 33_1 in the second horizontal direction (the Y direction) may be greater than the minimum width of the second portion 33_2 in the second horizontal direction (the Y direction). In an implementation, an average width of the first portion 33_1 in the second horizontal direction (the Y direction) may be greater than an average width of the second portion 33_2 in the second horizontal direction (the Y direction). In an implementation, a width of the first portion 33_1 at a middle vertical level in the second horizontal direction (the Y direction) may be greater than a width of the second portion 33_2 at a middle vertical level in the second horizontal direction (the Y direction).

In an implementation, the width L4 of the second portion 33_2 of the gate electrode 33 in the second horizontal direction (the Y direction) may decrease in the vertical direction (the Z direction), and then may increase. In an implementation, the width L4 of the second portion 33_2 in the second horizontal direction (the Y direction) may decrease along an upper surface of the semiconductor layer 31 in the vertical direction (the Z direction), and then may increase. An increased width or a decreased width of the width L4 of the second portion 33_2 in the second horizontal direction (the Y direction) may not be constant in the vertical direction (the Z direction).

In an implementation, the first portion 33_1 and the second portion 33_2 of the gate electrode 33 may overlap each other in the vertical direction (the Z direction). In an implementation, the first portion 33_1 of the gate electrode 33 may include a portion that does not overlap the second portion 33_2 in the vertical direction (the Z direction). In an implementation, the second portion 33_2 of the gate electrode 33 may not include a portion that does not overlap the first portion 33_1 in the vertical direction (the Z direction). In an implementation, as described above, the semiconductor layer 31 may be recessed toward the gate electrode 33 compared to the plurality of insulation layers 30, and the gate electrode 33 may have a shape that is recessed at a portion overlapping the semiconductor layer 31 in the second horizontal direction (the Y direction). In an implementation, the gate electrode 33 may have a shape which is recessed in the second horizontal direction (the Y direction).

In an implementation, an outer sidewall of the second portion 33_2 of the gate electrode 33 may be a curved shape. In an implementation, the vertical insulation layer VI that is conformally on the second portion 31_2 of the semiconductor layer 31 having a shape that is rounded at a boundary with the gate trench H, and the gate electrode 33 on the vertical insulation layer VI may include an outer sidewall that is rounded at the second portion 33_2 overlapping the semiconductor layer 31 in the second horizontal direction (the Y direction). In an implementation, a rounded shape of the outer sidewall of the second portion 33_2 of the gate electrode 33 may be complementary to a rounded shape of the second portion 31_2 of the semiconductor layer 31.

In an implementation, as illustrated in FIG. 6C, a width L5 of the first portion 33_1 of the gate electrode 33 in the first horizontal direction (the X direction) may be the same as a width L6 of the second portion 33_2 of the gate electrode 33 in the first horizontal direction (the X direction). In an implementation, a width of the gate electrode 33 in the first horizontal direction (the X direction) may be constant in the vertical direction (the Z direction). In an implementation, the gate electrode 33 may have a shape that is recessed at only a sidewall connected to the plurality of semiconductor layers 31. In an implementation, the gate electrode 33 may have a shape that is not recessed in the first horizontal direction (the X direction).

In an implementation, the plurality of gate electrodes 33 may be offset (e.g., misaligned) in the second horizontal direction (the Y direction). In an implementation, the center of the plurality of gate electrodes 33 may be offset in the second horizontal direction (the Y direction). In an implementation, a first gate electrode 33A between the first structure S1 and the second structure S2 may be offset in the second horizontal direction (the Y direction) with respect to a second gate electrode 33B between the second structure S2 and the third structure S3. In an implementation, a center CA of the first gate electrode 33A between the first structure S1 and the second structure S2 may be offset in the second horizontal direction (the Y direction) with respect to a center CB of the second gate electrode 33B between the second structure S2 and the third structure S3. In an implementation, the plurality of gate electrodes 33 may be arranged in zigzags in terms of a plane. In other words, a plurality of first gate electrodes 33A may be arranged to be staggered with a plurality of second gate electrodes 33B in terms of a plane (e.g., in a plan view).

In an implementation, a plurality of gate trenches H where the plurality of gate electrodes 33 are provided may be offset in the second horizontal direction (the Y direction). In an implementation, the plurality of gate trenches H may be arranged in zigzags in terms of a plane. In an implementation, the plurality of gate trenches H may be staggered with one another in terms of a plane.

In an implementation, each of the plurality of gate electrodes 33 between the plurality of structures S1 to S3 may be connected to the plurality of semiconductor layers 31. In an implementation, the first gate electrode 33A between the first structure S1 and the second structure S2 may be connected to the first semiconductor layer 31A and the second semiconductor layer 31B. In an implementation, the second gate electrode 33B between the second structure S2 and the third structure S3 may be connected to the second semiconductor layer 31B and the third semiconductor layer 31C. Herein, the gate electrode 33 being connected to the semiconductor layer 31 may denote that the gate electrode 33 and the semiconductor layer 31 are connected with each other through another element although not directly contacting each other.

In the semiconductor memory device 100 described above with reference to FIGS. 6A to 6C, the semiconductor layer 31 having a fin shape may be provided. As the semiconductor layer 31 having a fin shape is provided, a connected area between the semiconductor layer 31 and the gate electrode 33 may increase. Therefore, a thickness of the semiconductor layer 31 in the vertical direction (the Z direction) with respect to the same connected area may be reduced. In an implementation, herein, a width (referred to as a length of a side surface 31_S in the cross-sectional view of FIG. 6B) of the side surface 31_S of the semiconductor layer 31 may be defined as a width of a cell channel. Comparing with a case where a thickness of the semiconductor layer 31 having no fin shape is defined as a cell channel width, the semiconductor layer 31 may have the same thickness in the vertical direction (the Z direction), but a case where the semiconductor layer 31 has a fin shape may include a side surface which is greater than a case where the semiconductor layer 31 has no fin shape. Therefore, a semiconductor memory device may be provided where a cell channel width is not reduced even when a thickness in the vertical direction (the Z direction) decreases. In an implementation, a semiconductor memory device may be provided where a thickness in the vertical direction (the Z direction) decreases.

The semiconductor layer 31 having a fin shape may be provided by using the semiconductor memory device 100 described above with reference to FIGS. 6A to 6C, and the gate electrode 33 may be partially between vertical insulation layers VI in the vertical direction (the Z direction). In an implementation, coupling or interference between charge storage layers 35 including silicon nitride may be reduced. Therefore, a semiconductor memory device having enhanced performance and reliability may be provided.

In the semiconductor memory device 100 described above with reference to FIGS. 6A to 6C, the semiconductor layer 31 having a rounded shape may be provided. The semiconductor layer 31 having a rounded shape may be provided, and a field enhancement effect may decrease. In an implementation, in a case where a semiconductor layer has a fin shape without having a rounded shape, there may be a possibility that reliability is reduced due to the occurrence of a field enhancement effect in a right-angled corner portion. Herein, a shape where a corner portion of the semiconductor layer 31 having a fin shape is gently rounded may be provided, and thus, an erase voltage may be reduced by controlling a field enhancement effect. Therefore, a semiconductor memory device having enhanced performance and reliability may be provided.

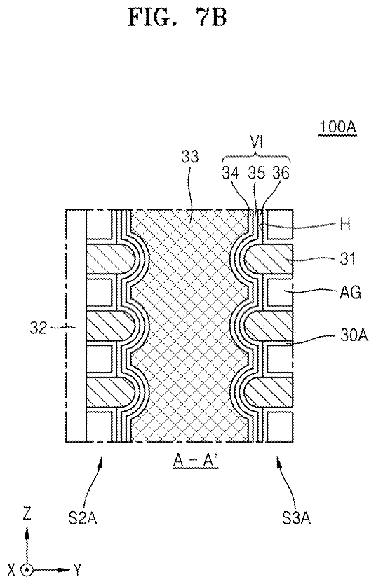

FIGS. 7A and 7B are diagrams for describing some elements of a semiconductor memory device 100A according to other embodiments. In detail, FIG. 7A is an enlarged plan view corresponding to the region RA of FIG. 3, and FIG. 7B is a cross-sectional view taken along line A-A′ of FIG. 7A. A difference with the semiconductor memory device 100 described above with reference to FIGS. 6A to 6C will be mainly described below.

Referring to FIGS. 7A and 7B, the semiconductor memory device 100A may include a plurality of structures S1A to S3A that are apart from one another in a second horizontal direction (the Y direction). Each of the plurality of structures SIA to S3A may include a plurality of semiconductor layers 31 and a plurality of insulation layers 30A, which are stacked in the vertical direction (the Z direction).

In an implementation, an interlayer insulation layer 32 may be between the plurality of structures SIA to S3A. In an implementation, a plurality of gate trenches H may pass through the interlayer insulation layer 32, between the plurality of structures S1A to S3A, in the vertical direction (the Z direction). In an implementation, a plurality of gate electrodes 33 extending in the vertical direction (the Z direction) may be in each of the plurality of gate trenches H. A plurality of vertical insulation layers VI extending in the vertical direction (the Z direction) may be between the plurality of gate electrodes 33 and a sidewall of each of the plurality of gate trenches H. Each of the plurality of vertical insulation layers VI may include a blocking dielectric layer 34, a charge storage layer 35, and a tunneling dielectric layer 36, which are sequentially arranged on an outer sidewall of each of the plurality of gate electrodes 33.

In an implementation, a plurality of air gaps AG may be between the plurality of semiconductor layers 31 in the vertical direction (the Z direction). In an implementation, the air gap AG may be surrounded by the insulation layer 30A between the plurality of semiconductor layers 31. In an implementation, the air gap AG may denote an empty internal space of the insulation layer 30A. In an implementation, the plurality of semiconductor layers 31 may be apart from one another with the air gap AG therebetween. The plurality of semiconductor layers 31 may be apart from one another with the air gap AG and the insulation layer 30A therebetween.

In an implementation, each of the plurality of air gaps AG may be apart from the vertical insulation layer VI with the insulation layer 30A therebetween. In an implementation, each of the plurality of air gaps AG may be apart from the gate electrode 33 with the insulation layer 30A and the vertical insulation layer VI therebetween.

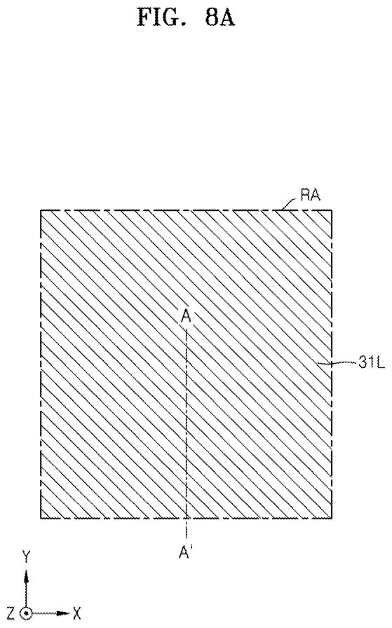

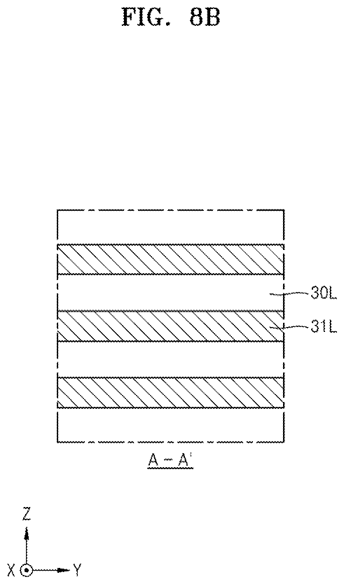

FIGS. 8A to 13B are diagrams for describing a method of manufacturing some elements of a semiconductor memory device, according to an embodiment. In detail, FIGS. 8A, 9A, 10A, 11A, 12A, and 13A are enlarged plan views corresponding to the region RA of FIG. 3, and FIGS. 8B, 9B, 10B, 11B, 12B, and 13B are cross-sectional views taken along lines A-A′ of FIGS. 8A, 9A, 10A, 11A, 12A, and 13A, respectively.

Referring to FIGS. 8A and 8B, a plurality of pre-semiconductor layers 31L and a plurality of pre-insulation layers 30L may be alternately stacked in the vertical direction (the Z direction). The plurality of pre-semiconductor layers 31L and the plurality of pre-insulation layers 30L may extend in a first horizontal direction (the X direction) and a second horizontal direction (the Y direction).

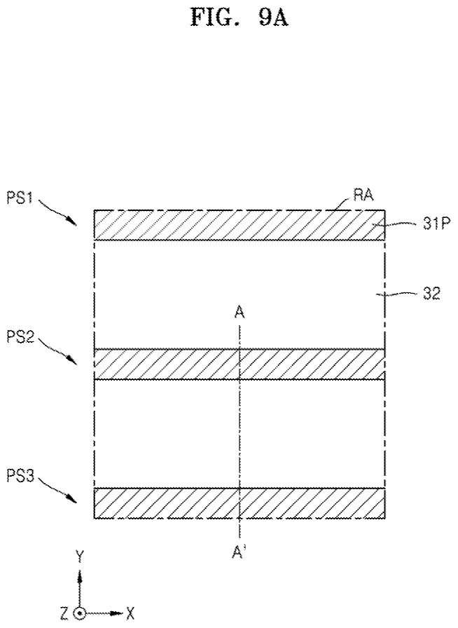

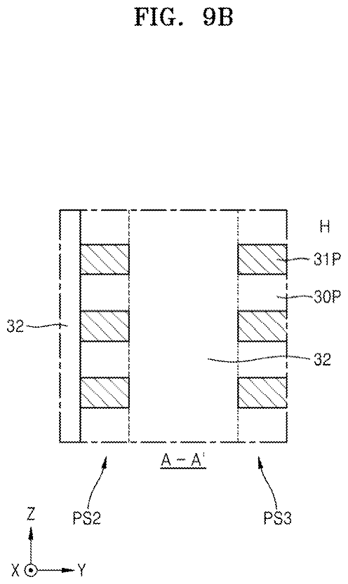

Referring to FIGS. 9A and 9B, a plurality of pre-structures PS1 to PS3 apart from one another in the second horizontal direction (the Y direction) may be formed by simultaneously patterning the plurality of pre-semiconductor layers 31L and the plurality of pre-insulation layers 30L. Each of the plurality of pre-structures PS1 to PS3 may include a plurality of semiconductor patterns 31P and a plurality of insulation patterns 30P, which are alternately stacked in the vertical direction (the Z direction). An interlayer insulation layer 32 may be between the plurality of pre-structures PS1 to PS3. In other words, the plurality of pre-structures PS1 to PS3 may be apart from one another with the interlayer insulation layer 32 therebetween.

In an implementation, widths of the plurality of semiconductor patterns 31P and the plurality of insulation patterns 30P in the second horizontal direction (the Y direction) may be equal to one another.

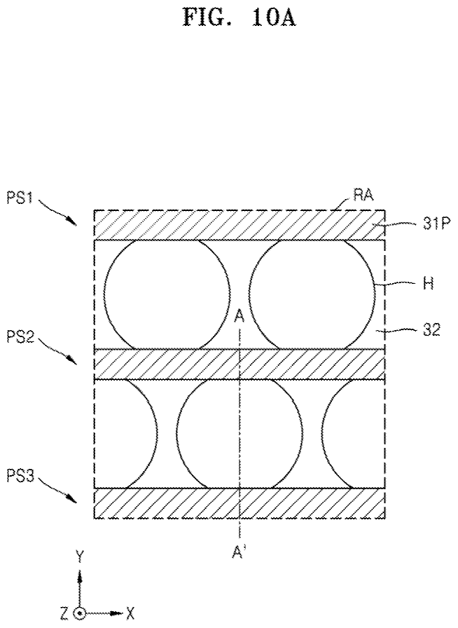

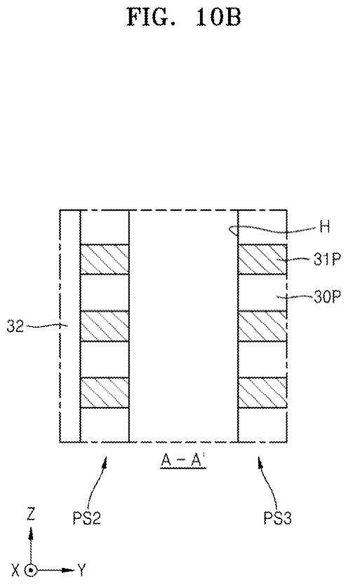

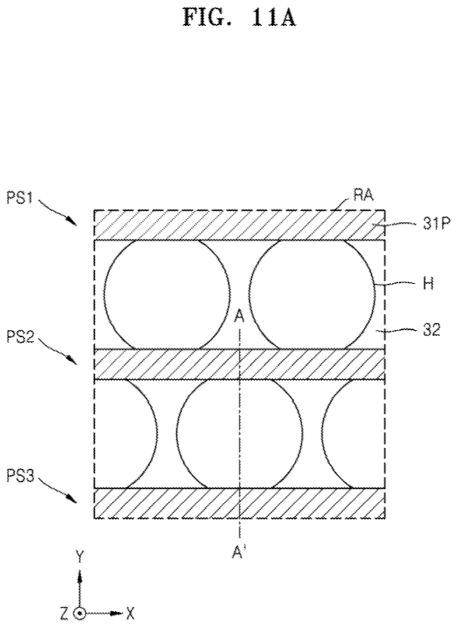

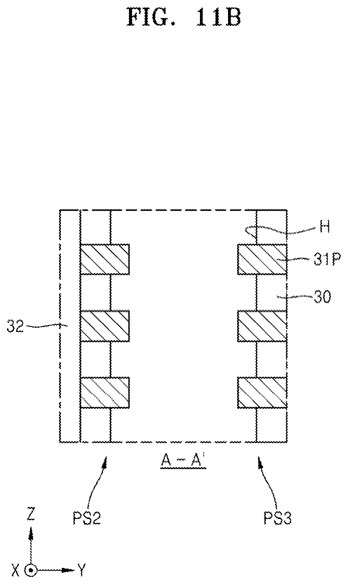

Referring to FIGS. 10A and 10B, a plurality of gate trenches H may be formed through the interlayer insulation layer 32 in the vertical direction (the Z direction). In an implementation, the plurality of gate trenches H may be between two adjacent pre-structures of the plurality of pre-structures PS1 to PS3.

In an implementation, in a process of etching the interlayer insulation layer 32 to form the plurality of gate trenches H, when only the interlayer insulation layer 32 is etched, as illustrated in FIG. 10A, a portion of a plane-shaped arc of each of the plurality of gate trenches H may be rectilinearly formed. In an implementation, in a case where the interlayer insulation layer 32 and a portion of each of the plurality of pre-structures PS1 to PS3 are etched together, a planar shape of each of the plurality of gate trenches H may be a circle.

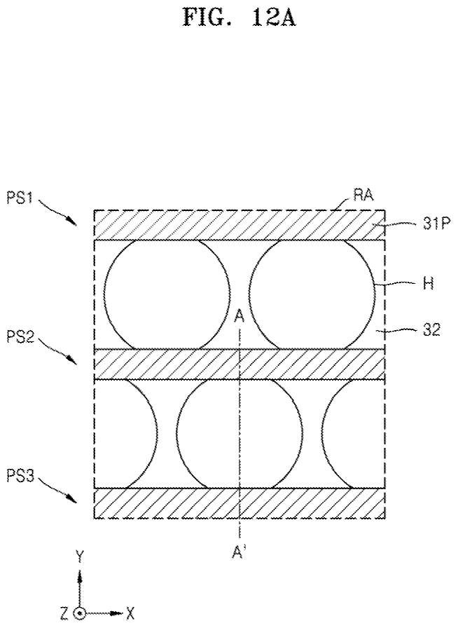

Referring to FIGS. 11A and 11B, a plurality of insulation layers 30 may be formed by etching a portion of each of the plurality of insulation patterns 30P of each of the plurality of pre-structures PS1 to PS3. In detail, a portion of each of sidewalls of the plurality of insulation patterns 30P exposed through the plurality of gate trenches H may be etched. In an implementation, the plurality of insulation patterns 30P may include silicon oxide, and a portion of each of the plurality of insulation patterns 30P may be etched by using an etching material capable of etching silicon oxide. In an implementation, a portion of each of the plurality of insulation patterns 30P may be etched by using a wet etching process. In an implementation, comparing with the plurality of semiconductor patterns 31P, the plurality of insulation layers 30 may have a shape which is recessed in the second horizontal direction (the Y direction).

In an implementation, a width of the plurality of insulation layers 30 in the second horizontal direction (the Y direction) may be less than a width of the plurality of semiconductor patterns 31P in the second horizontal direction (the Y direction). In an implementation, a contact surface, contacting the interlayer insulation layer 32, of each of the plurality of insulation layers 30 may be aligned with a contact surface, contacting the interlayer insulation layer 32, of each of the plurality of semiconductor patterns 31P in the vertical direction (the Z direction). In an implementation, only one side surface of each of the plurality of insulation patterns 30P exposed through the plurality of gate trenches H may be etched. In an implementation, the other side surface, which is not exposed through the plurality of gate trenches H, of each of the plurality of insulation patterns 30P may not be etched.

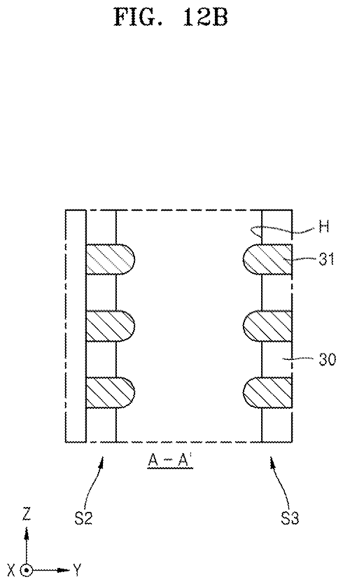

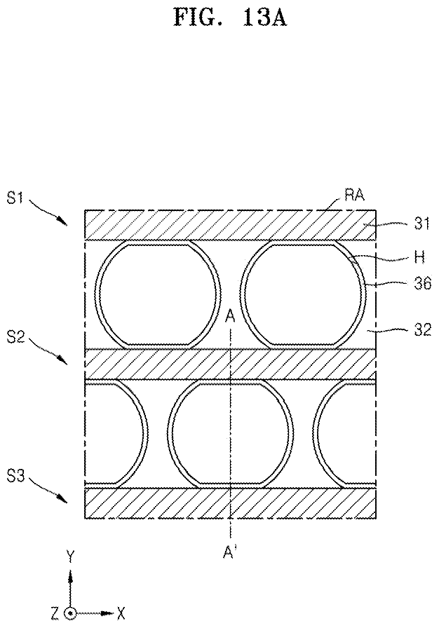

Referring to FIGS. 12A and 12B, a plurality of semiconductor layers 31 may be formed by etching a portion of each of the plurality of semiconductor patterns 31P of each of the plurality of pre-structures PS1 to PS3. In an implementation, a portion of each of the plurality of semiconductor patterns 31P exposed through the plurality of gate trenches H may be etched. In an implementation, the plurality of semiconductor layers 31 having a rounded shape may be formed by etching an angled portion of each of the plurality of semiconductor patterns 31P. In an implementation, the plurality of semiconductor patterns 31P may include polysilicon and may be etched by oxidizing polysilicon. In an implementation, a portion of each of the plurality of semiconductor patterns 31P may be etched by using a wet etching process. In an implementation, a wet etching process included in a process of etching a portion of each of the plurality of semiconductor patterns 31P to form the plurality of semiconductor layers 31 may be weaker in stiffness than a wet etching process included in a process of etching a portion of each of the plurality of insulation patterns 30P to form the plurality of insulation layers 30. In an implementation, a process time may be relatively shorter, or a concentration of etching materials may be relatively lower.

In an implementation, a width L1 of the semiconductor layer 31 in the second horizontal direction (the Y direction) may be greater than a width L2 of the insulation layer 30 in the second horizontal direction (the Y direction). In an implementation, the semiconductor layer 31 may have a shape that is rounded at a boundary with the gate trench H.

Through the process, a plurality of structures S1 to S3 may be formed where the plurality of semiconductor layers 31 and the plurality of insulation layers 30 are alternately stacked in the vertical direction (the Z direction).

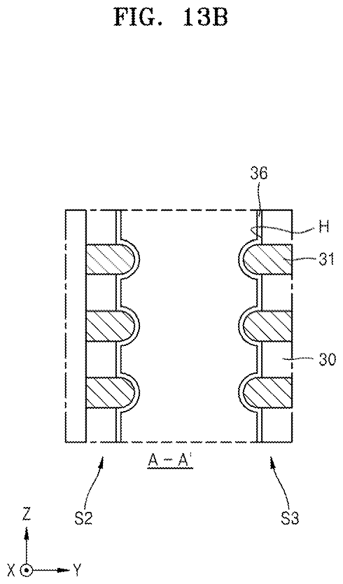

Referring to FIGS. 13A and 13B, a tunneling dielectric layer 36 may be formed on the gate trench H. The tunneling dielectric layer 36 may be conformally formed on a sidewall of the insulation layer 30 and a sidewall of the semiconductor layer 31. The tunneling dielectric layer 36 may be conformally formed on the sidewall of the insulation layer 30 and the sidewall of the semiconductor layer 31, which are not aligned with each other in the vertical direction (the Z direction). The tunneling dielectric layer 36 may be conformally formed on the sidewall of the semiconductor layer 31 having a round shape.

Referring again to FIGS. 6A and 6B, a vertical insulation layer VI may be formed by sequentially forming a charge storage layer 35 and a blocking dielectric layer 34 on the tunneling dielectric layer 36. Subsequently, a semiconductor memory device 100 may be manufactured by forming a gate electrode 33 filling the gate trench H.

One or more embodiments may provide a semiconductor memory device including a vertical gate electrode.

One or more embodiments may provide a semiconductor memory device where

a thickness is reduced in a vertical direction.

One or more embodiments may provide a semiconductor memory device where performance and reliability are enhanced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made without departing from the spirit and scope of the present invention as set forth in the following claims.

What is claimed is:

1. A semiconductor memory device, comprising:
a plurality of structures including a plurality of insulation layers and a plurality of semiconductor layers alternately stacked in a vertical direction, the plurality of structures being spaced apart from one another in a horizontal direction;
an interlayer insulation layer between the plurality of structures;
a plurality of gate electrodes respectively in a plurality of gate trenches passing through the interlayer insulation layer in the vertical direction, between the plurality of structures, the plurality of gate electrodes connected to the plurality of semiconductor layers; and
a plurality of vertical insulation layers respectively on sidewalls of the plurality of gate trenches,
wherein:
each gate electrode of the plurality of gate electrodes includes a plurality of first portions overlapping the plurality of insulation layers in the horizontal direction and a plurality of second portions overlapping the plurality of semiconductor layers in the horizontal direction, and
a first width of each first portion of the plurality of first portions in the horizontal direction is greater than a second width of each second portion of the plurality of second portions in the horizontal direction.

2. The semiconductor memory device as claimed in claim 1, wherein a contact surface between a sidewall of each of the plurality of gate trenches and a sidewall of a corresponding semiconductor layer of the plurality of semiconductor layers is a curved surface.

3. The semiconductor memory device as claimed in claim 1, wherein each semiconductor layer of the plurality of semiconductor layers includes a first portion overlapping the plurality of insulation layers in the vertical direction and a second portion that does not overlap the plurality of insulation layers in the vertical direction.

4. The semiconductor memory device as claimed in claim 3, wherein the second portion of each semiconductor layer of the plurality of semiconductor layers has a shape that is rounded at a boundary with the plurality of gate trenches.

5. The semiconductor memory device as claimed in claim 1, wherein the plurality of gate trenches are offset in the horizontal direction.

6. The semiconductor memory device as claimed in claim 1, wherein the second width decreases toward an upper surface of each semiconductor layer of the plurality of semiconductor layers from a lower surface of each semiconductor layer of the plurality of semiconductor layers, and then increases.

7. The semiconductor memory device as claimed in claim 1, wherein each vertical insulation layer of the plurality of vertical insulation layers includes a blocking dielectric layer, a charge storage layer, and a tunneling dielectric layer, that are sequentially arranged on each of outer sidewalls of the plurality of gate electrodes.

8. A semiconductor memory device, comprising:
a first structure including a plurality of first insulation layers and a plurality of first semiconductor layers, which are alternately stacked in a vertical direction;
a second structure including a plurality of second insulation layers and a plurality of second semiconductor layers, which are alternately stacked in the vertical direction, the second structure being spaced apart from the first structure in a first horizontal direction;
a third structure including a plurality of third insulation layers and a plurality of third semiconductor layers, which are alternately stacked in the vertical direction, the third structure being spaced apart from the second structure in the first horizontal direction;
a first interlayer insulation layer between the first structure and the second structure;
a second interlayer insulation layer between the second structure and the third structure;
a plurality of first gate electrodes respectively in a plurality of first gate trenches aligned in a second horizontal direction intersecting with the first horizontal direction, passing through the first interlayer insulation layer in the vertical direction, and connected to the plurality of first semiconductor layers and the plurality of second semiconductor layers; and
a plurality of second gate electrodes respectively in a plurality of second gate trenches aligned in the second horizontal direction, passing through the second interlayer insulation layer in the vertical direction, and connected to the plurality of second semiconductor layers and the plurality of third semiconductor layers,
wherein:
a center of each first gate electrode of the plurality of first gate electrodes and a center of each second gate electrode of the plurality of second gate electrodes are offset in the first horizontal direction, and
a width of each first semiconductor layer of the plurality of first semiconductor layers in the first horizontal direction is greater than a width of each first insulation layer of the plurality of first insulation layers in the first horizontal direction.

9. The semiconductor memory device as claimed in claim 8, further comprising a plurality of vertical insulation layers respectively on inner sidewalls of the plurality of first gate trenches.

10. The semiconductor memory device as claimed in claim 9, wherein each vertical insulation layer of the plurality of vertical insulation layers includes a blocking dielectric layer, a charge storage layer, and a tunneling dielectric layer, which are sequentially arranged on each of outer sidewalls of the plurality of first gate electrodes.

11. The semiconductor memory device as claimed in claim 8, wherein a contact surface between a sidewall of each first gate trench of the plurality of first gate trenches and a sidewall of a corresponding first semiconductor layer of the plurality of first semiconductor layers is a curved surface.

12. The semiconductor memory device as claimed in claim 8, wherein each first semiconductor layer of the plurality of first semiconductor layers includes a first portion overlapping the plurality of first insulation layers in the vertical direction and a second portion that does not overlap the plurality of first insulation layers in the vertical direction.

13. The semiconductor memory device as claimed in claim 12, wherein the second portion of each first semiconductor layer of the plurality of first semiconductor layers has a shape that is rounded at a boundary with the plurality of first gate trenches.

14. The semiconductor memory device as claimed in claim 8, wherein:
each first gate electrode of the plurality of first gate electrodes includes a plurality of first portions overlapping the plurality of first insulation layers in the first horizontal direction and a plurality of second portions overlapping the plurality of first semiconductor layers in the first horizontal direction, and
a first width of each first portion of the plurality of first portions of each first gate electrode of the plurality of first gate electrodes in the first horizontal direction is greater than a second width of each second portion of the plurality of second portions in the first horizontal direction.

15. The semiconductor memory device as claimed in claim 14, wherein a width of each first portion of the plurality of first portions of each first gate electrode of the plurality of first gate electrodes in the second horizontal direction is equal to a width of each second portion of the plurality of second portions of each first gate electrode of the plurality of first gate electrodes in the second horizontal direction.

16. A semiconductor memory device, comprising:
a plurality of structures including a plurality of insulation layers and a plurality of semiconductor layers alternately stacked in a vertical direction, the plurality of structures being spaced apart from one another in a first horizontal direction;
an interlayer insulation layer between the plurality of structures;
a plurality of gate electrodes respectively in a plurality of gate trenches passing through the interlayer insulation layer in the vertical direction, between the plurality of structures, the plurality of gate electrodes being connected to the plurality of semiconductor layers; and
a plurality of vertical insulation layers respectively on inner sidewalls of the plurality of gate trenches,
wherein:
each gate electrode of the plurality of gate electrodes includes a plurality of first portions overlapping the plurality of insulation layers in the first horizontal direction and a plurality of second portions overlapping the plurality of semiconductor layers in the first horizontal direction,
a first width of each first portion of the plurality of first portions in the first horizontal direction is greater than a second width of each second portion of the plurality of second portions in the first horizontal direction,
a width of each first portion of the plurality of first portions in a second horizontal direction is equal to a width of each second portion of the plurality of second portions in the second horizontal direction,
the plurality of gate trenches are arranged in zigzags in a plan view, and each semiconductor layer of the plurality of semiconductor layers has a shape that is rounded at a contact surface with the plurality of gate trenches.

17. The semiconductor memory device as claimed in claim 16, wherein each vertical insulation layer of the plurality of vertical insulation layers includes a blocking dielectric layer, a charge storage layer, and a tunneling dielectric layer, which are sequentially arranged on each outer sidewall of the plurality of gate electrodes.

18. The semiconductor memory device as claimed in claim 16, wherein each semiconductor layer of the plurality of semiconductor layers includes a first portion overlapping the plurality of insulation layers in the vertical direction and a second portion that does not overlap the plurality of insulation layers in the vertical direction.

19. The semiconductor memory device as claimed in claim 16, wherein the second width decreases toward an upper surface of each semiconductor layer of the plurality of semiconductor layers from a lower surface of each semiconductor layer of the plurality of semiconductor layers, and then increases.

20. The semiconductor memory device as claimed in claim 16, wherein a portion, contacting each semiconductor layer of the plurality of semiconductor layers, of each vertical insulation layer of the plurality of vertical insulation layers has a rounded shape.
